(19) United States
(12) Patent Application Publication
(10) Pub. No.: US 2024/0194816 A1
(43) Pub. Date: Jun. 13, 2024

(54) METHOD OF MANUFACTURING OPTICAL DETECTION ELEMENT AND OPTICAL DETECTION ELEMENT

(71) Applicant: HAMAMATSU PHOTONICS K.K., Hamamatsu-shi (JP)

(72) Inventors: Kazutoshi NAKAJIMA, Hamamatsu-shi (JP); Wei DONG, Hamamatsu-shi (JP); Hiroyasu FUJIWARA, Hamamatsu-shi (JP)

(73) Assignee: HAMAMATSU PHOTONICS K.K., Hamamatsu-shi (JP)

(21) Appl. No.: 18/529,176

(22) Filed: Dec. 5, 2023

(30) Foreign Application Priority Data
Dec. 9, 2022 (JP) 2022-196876

(51) Int. Cl. H01L 31/108; H01L 31/18

(52) U.S. Cl. CPC H01L 31/1085; H01L 31/1804

(57) ABSTRACT

A method of manufacturing an optical detection element includes: a first process of forming an amorphous semiconductor layer on a support; a second process of forming a first metal layer on the semiconductor layer; a third process of carrying out a heat treatment so that the semiconductor layer is polycrystallized and the semiconductor layer and the first metal layer are interchanged with each other, thereby forming the first metal layer on the support and forming a polycrystalline photoelectric conversion layer on the first metal layer; and a fourth process of forming a second metal layer on the photoelectric conversion layer. In the fourth process, the second metal layer is formed so that a width of the second metal layer becomes a width with which surface plasmon resonance occurs due to incidence of light in a predetermined wavelength region.

### TECHNICAL FIELD

The present disclosure relates to a method of manufacturing an optical detection element and an optical detection element.

### BACKGROUND

As an optical detection element having sensitivity to light in an infrared region, research is being actively conducted on an optical detection element based on a silicon substrate instead of an expensive compound semiconductor substrate. As the optical detection element, International Publication WO 2013/183343 discloses an optical detector including a substrate, a first metal layer formed on the substrate, a semiconductor structure layer formed on the first metal layer, a second metal layer formed on the semiconductor structure layer. In the optical detector, the semiconductor structure layer utilizes optical absorption of quantum inter-subband transition, and electrons are excited by plasmon resonance.

### SUMMARY

However, in the optical detection element described above, there is a problem that the semiconductor structure layer is required to carry out various kinds of processing under a high temperature and a high pressure while maintaining a fine layer structure, and a manufacturing process becomes complicated.

An object of the present disclosure is to provide a method of manufacturing an optical detection element which can easily manufacture an optical detection element with high sensitivity to light in a predetermined wavelength region, and an optical detection element.

A method of manufacturing an optical detection element according to an aspect of the present disclosure is “a method of manufacturing an optical detection element, including: a first process of forming an amorphous semiconductor layer on a support; a second process of forming a first metal layer on the semiconductor layer; a third process of carrying out a heat treatment so that the semiconductor layer is polycrystallized and the semiconductor layer and the first metal layer are interchanged with each other, thereby forming the first metal layer on the support and forming a polycrystalline photoelectric conversion layer on the first metal layer; and a fourth process of forming a second metal layer on the photoelectric conversion layer, wherein in the fourth process, the second metal layer is formed so that a width of the second metal layer in a first direction orthogonal to a thickness direction of the second metal layer becomes a width with which surface plasmon resonance occurs due to incidence of light in a predetermined wavelength region”.

An optical detection element according to another aspect of the present disclosure is “an optical detection element including: a support; a first metal layer formed on the support; a polycrystalline photoelectric conversion layer formed on the first metal layer; and a second metal layer formed on the photoelectric conversion layer, wherein a width of the second metal layer in a first direction orthogonal to a thickness direction of the second metal layer is a width with which surface plasmon resonance occurs due to incidence of light in a predetermined wavelength region”.

### BRIEF DESCRIPTION OF THE DRAWINGS

FIG. 1 is a plan view of an optical detection element of an embodiment.

FIG. 2 is a cross-sectional view of the optical detection element illustrated in FIG. 1.

FIGS. 3A to 3D are views illustrating a method of manufacturing the optical detection element illustrated in FIG. 1.

FIG. 4 is a view illustrating simulation results of an absorption wavelength region with an optical detection element of an Example.

FIG. 5 is a plan view of an optical detection element of a Modification Example.

FIG. 6 is a plan view of an optical detection element of a Modification Example.

### DETAILED DESCRIPTION

Hereinafter, an embodiment of the present disclosure will be described in detail with reference to the accompanying drawings. Note that, in the drawings, the same reference numeral will be given to the same or equivalent portion, and redundant description will be omitted.

### [Configuration of Optical Detection Element]

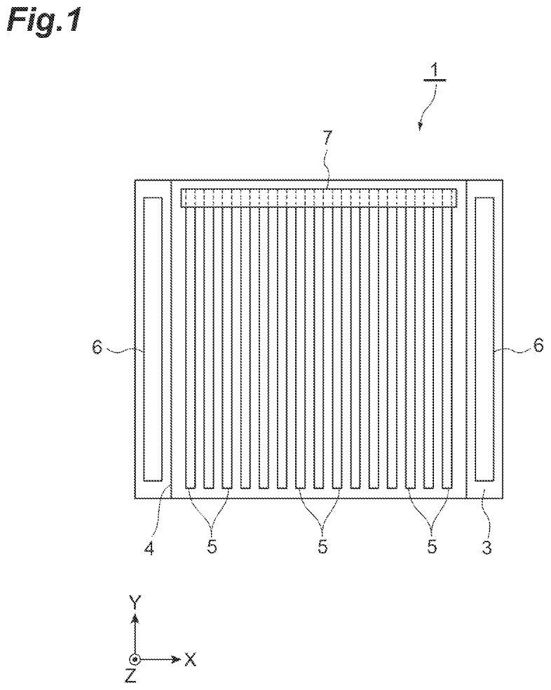

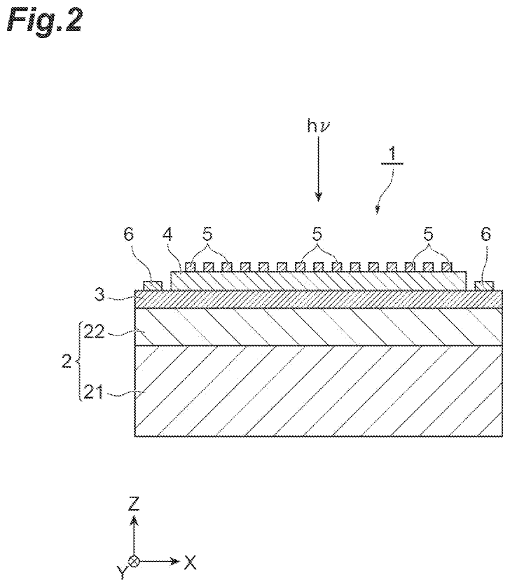

As illustrated in FIG. 1 and FIG. 2, an optical detection element 1 includes a support 2, a first metal layer 3, a photoelectric conversion layer 4, a plurality of second metal layers 5, a pair of first electrodes 6, and a second electrode 7. The optical detection element 1 is an element that detects light hv in a short-wave infrared region (light in a predetermined wavelength region). Hereinafter, an incident direction of the light hv is referred to as a Z-direction, a direction orthogonal to the Z-direction is referred to as an X-direction, and a direction orthogonal to both the Z-direction and the X-direction is referred to as a Y-direction.

The support 2 is a semiconductor substrate in which the Z-direction is set as a thickness direction. More specifically, the support 2 includes a silicon substrate 21, and a silicon oxide film 22 formed on the silicon substrate 21. The support 2 is formed, for example, in a rectangular plate shape. The thickness of the silicon substrate 21 is, for example, approximately 500 μm. The thickness of the silicon oxide film 22 is, for example, approximately 1 μm.

The first metal layer 3 is formed on the silicon oxide film 22 with the Z-direction set as a thickness direction. That is, the first metal layer 3 is formed on the support 2 with the Z-direction set as the thickness direction. A material of the first metal layer 3 is, for example, Au or Al. The thickness of the first metal layer 3 is, for example, approximately 50 to 100 nm.

The photoelectric conversion layer 4 is formed on the first metal layer 3 (more specifically, a surface opposite to the support 2 in the first metal layer 3) with the Z-direction set as a thickness direction. The photoelectric conversion layer 4 is not formed in a region along each side parallel to the Y-direction on the surface opposite to the support 2 in the first metal layer 3. The photoelectric conversion layer 4 is a P-type polycrystalline layer formed from a material containing any one among Ge, Si, Si—Ge, and Ge—Sn. The thickness of the photoelectric conversion layer 4 is, for example, approximately 50 nm. Note that, Si—Ge represents a mixture of Si and Ge. In addition, Ge—Sn represents a mixture of Ge and Sn.

The plurality of second metal layers 5 are formed on the photoelectric conversion layer 4 (more specifically, a surface opposite to the first metal layer 3 in the photoelectric conversion layer 4) with the Z-direction set as a thickness direction. A width of each of the second metal layers 5 in the X-direction (a first direction orthogonal to the thickness direction of the second metal layer 5) is set to a width with which surface plasmon resonance occurs due to incidence of the light hv in a short-wave infrared region. Each of the second metal layers 5 extends in a long shape with the Y-direction (a second direction orthogonal to both the thickness direction of the second metal layer 5 and the first direction) set as a longitudinal direction. The plurality of the second metal layers 5 are arranged with a predetermined pitch in the X-direction in a state of being separated from each other. A material of the second metal layers 5 is, for example, Ti, Ti/Au, or Ti/Al. Note that, “α/β” represents a configuration in which an α layer and a β layer are formed on the photoelectric conversion layer 4 in this order. A width of each of the second metal layers 5 in the X-direction is, for example, approximately 300 nm. A distance (that is, a pitch) between centers of the second metal layers 5 adjacent to each other is, for example, approximately 600 nm. The thickness of each of the second metal layers 5 is, for example, approximately 100 nm.

In this embodiment, the first metal layer 3 forms an ohmic junction with the P-type photoelectric conversion layer 4, and each of the second metal layers 5 forms a Schottky junction with the P-type photoelectric conversion layer 4. According to this, a Schottky diode is constituted.

The pair of first electrodes 6 are formed on the first metal layer 3. Each of the first electrodes 6 extends in the Y-direction in a region along each side parallel to the Y-direction on the surface opposite to the support 2 in the first metal layer 3. The second electrode 7 is formed on the photoelectric conversion layer 4. In a region along a side parallel to the X-direction on a surface opposite to the first metal layer 3 in the photoelectric conversion layer 4, the second electrode 7 extends in the X-direction over the plurality of second metal layers 5.

In the optical detection element 1 configured as described above, when the light hv in a short-wave infrared region is incident, surface plasmon resonance occurs between the first metal layer 3 and each of the second metal layers 5 due to polarized light whose electric field direction is the X-direction in the light hv, and light condensing efficiency in the photoelectric conversion layer 4 can be raised due to an optical antenna effect. In addition, in a state in which the light condensing efficiency in the photoelectric conversion layer 4 is raised, polarized light whose electric field direction is the X-direction is absorbed in the photoelectric conversion layer 4, and charges generated in the photoelectric conversion layer 4 are output as a current signal from the second electrode 7. In this manner, in the optical detection element 1, the light condensing efficiency in the photoelectric conversion layer 4 is raised due to the optical antenna effect, and as a result, sensitivity to the light hv in a short-wave infrared region is raised. Accordingly, according to the optical detection element 1, the light hv in a short-wave infrared region can be detected with high sensitivity.

### [Method of Manufacturing Optical Detection Element]

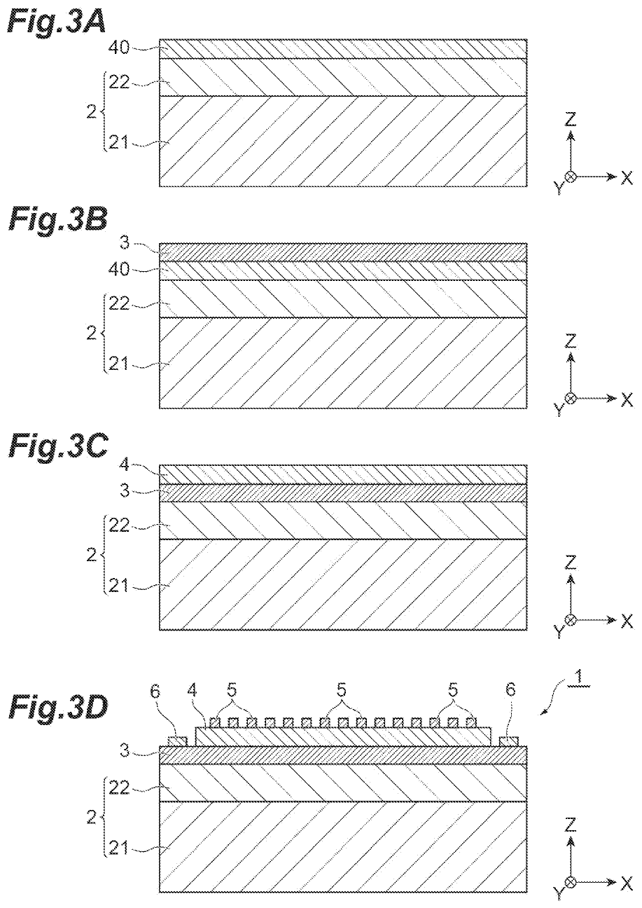

A method of manufacturing the above-described optical detection element 1 will be described. First, as illustrated in FIG. 3A, an amorphous semiconductor layer 40 is formed on the support 2 (first process). In the first process, the semiconductor layer 40 is formed by a material containing any one among Ge, Si, Si—Ge, and Ge—Sn. As an example, the amorphous semiconductor layer 40 is formed on the silicon oxide film 22 by RF sputtering.

Next, as illustrated in FIG. 3B, the first metal layer 3 is formed on the semiconductor layer 40 (second process). As an example, the first metal layer 3 is formed on the semiconductor layer 40 by vacuum evaporation.

Next, a heat treatment is carried out so that the semiconductor layer 40 is polycrystallized, and the semiconductor layer 40 and the first metal layer 3 are interchanged with each other, and according to the heat treatment, as illustrated in FIG. 3C, the first metal layer 3 is formed on the support 2, and the polycrystalline photoelectric conversion layer 4 is formed on the first metal layer 3 (third process). In this embodiment, the amorphous semiconductor layer 40 is changed into the P-type polycrystalline photoelectric conversion layer 4 due to a catalytic effect of the first metal layer 3. In the third process, the heat treatment is carried out at a temperature of 250° C. to 500° C. (more preferably, at a temperature of 300° C. to 400° C.). The heat treatment is carried out in an inert gas atmosphere such as nitrogen for from several hours to more than ten hours. As an example, the heat treatment is carried out in a nitrogen atmosphere at a temperature of 350° C. for 12 hours. This heat treatment is called a metal-induced-crystallization (MIC) method. Note that, description of “the semiconductor layer 40 and the first metal layer 3 are interchanged with each other” represents that the first metal layer 3 migrates to a support 2 side with respect to the semiconductor layer 40, and as a result, the first metal layer 3 is formed on the support 2 side with respect to the photoelectric conversion layer 4.

Next, as illustrated in FIG. 3D, the plurality of second metal layers 5 are formed on the photoelectric conversion layer 4 (fourth process). In the fourth process, the plurality of second metal layers 5 are formed so that a width of each of the second metal layers 5 in the X-direction becomes a width with which surface plasmon resonance occurs due to incidence of the light hv in a short-wave infrared region. In other words, in the fourth process, the plurality of second metal layers 5 are formed so that the width of each of the second metal layers 5 in the X-direction becomes a width with which surface plasmon resonance occurs due to incidence of light with a wavelength of 0.9 μm to 1.8 μm. In addition, in the fourth process, the plurality of second metal layers 5 are formed so that each of the second metal layers 5 extends in a long shape with the Y-direction set as a longitudinal direction and the plurality of second metal layers 5 are arranged in the X-direction. As an example, patterning of the plurality of second metal layers 5 is carried out by an electron beam exposure method and a lift-off method.

Next, the pair of the first electrodes 6 are formed on the first metal layer 3, and the second electrode 7 is formed on the photoelectric conversion layer 4 and the plurality of second metal layers 5. From the above-described processes, the optical detection element 1 is obtained.

As described above, in the method of manufacturing the optical detection element 1, after the amorphous semiconductor layer 40 is formed on the support 2, and the first metal layer 3 is formed on the semiconductor layer 40, the heat treatment is carried out so that the semiconductor layer 40 is polycrystallized and the semiconductor layer 40 and the first metal layer 3 are interchanged with each other. According to this, it is possible to easily obtain a configuration in which the first metal layer 3 and the polycrystalline photoelectric conversion layer 4 are formed on the support 2 in this order. Furthermore, the plurality of second metal layers 5 are formed on the photoelectric conversion layer 4 so that the width of each of the second metal layers 5 in the X-direction becomes a width with which surface plasmon resonance occurs due to incidence of the light hv in a short-wave infrared region. According to this, in the optical detection element 1, when the light hv in a short-wave infrared region is incident, surface plasmon resonance occurs between the first metal layer 3 and each of the second metal layers 5 due to polarized light whose electric field direction is the X-direction in the light hv, and light condensing efficiency in the photoelectric conversion layer 4 is raised due to the optical antenna effect, and as a result, sensitivity to the light hv in a short-wave infrared region is raised. Accordingly, according to the method of manufacturing the optical detection element 1, it is possible to easily manufacture the optical detection element 1 having high sensitivity to the light hv in a short-wave infrared region.

Note that, in a state in which the first metal layer 3 is formed on the support 2, and the amorphous semiconductor layer 40 is formed on the first metal layer 3, when the heat treatment is carried out so that the semiconductor layer 40 is polycrystallized, the first metal layer 3 and the semiconductor layer 40 are interchanged with each other, and thus there is a concern that the polycrystalline photoelectric conversion layer 4 may be formed on the support 2 and the first metal layer 3 may be formed on the photoelectric conversion layer 4. That is, in a method other than the above-described method of manufacturing the optical detection element 1, it is very difficult to obtain the configuration in which the first metal layer 3 and the polycrystalline photoelectric conversion layer 4 are formed on the support 2 in this order.

In the method of manufacturing the optical detection element 1, in the first process, the semiconductor layer 40 is formed by a material containing any one among Ge, Si, Si—Ge, and Ge—Sn. According to this, in the polycrystalline photoelectric conversion layer 4 formed by the material containing any one among Ge, Si, Si—Ge, and Ge—Sn, photoelectric conversion efficiency can be raised with respect to the light hv in a short-wave infrared region.

In the method of manufacturing the optical detection element 1, in the fourth process, the plurality of second metal layers 5 are formed so that the width of each of the second metal layers 5 in the X-direction becomes a width with which surface plasmon resonance occurs due to incidence of light with a wavelength of 0.9 μm to 1.8 μm. According to this, light condensing efficiency in the photoelectric conversion layer 4 can be raised with respect to the light hv in a short-wave infrared region.

In the method of manufacturing the optical detection element 1, in the fourth process, the plurality of second metal layers 5 are formed so that each of the second metal layers 5 extends in a long shape with the Y-direction set as a longitudinal direction. According to this, it is possible to obtain the optical detection element 1 that can detect polarized light whose electric field direction is the X-direction in the light hv in a short-wave infrared region in the entirety of the second metal layers 5 extending in the Y-direction.

In the method of manufacturing the optical detection element 1, in the fourth process, the plurality of second metal layers 5 are formed to be arranged in the X-direction. According to this, it is possible to obtain the optical detection element 1 that can detect polarized light whose electric field direction is the X-direction in the light hv in a short-wave infrared region in a wide region parallel to both the X-direction and the Y-direction.

In the method of manufacturing the optical detection element 1, in the third process, the heat treatment is carried out at a temperature of 250° C. to 500° C. According to this, since polycrystallization of the semiconductor layer 40 and interchanging of the semiconductor layer 40 and the first metal layer 3 are appropriately realized, it is possible to reliably obtain a configuration in which the first metal layer 3 and the polycrystalline photoelectric conversion layer 4 are formed on the support 2 in this order.

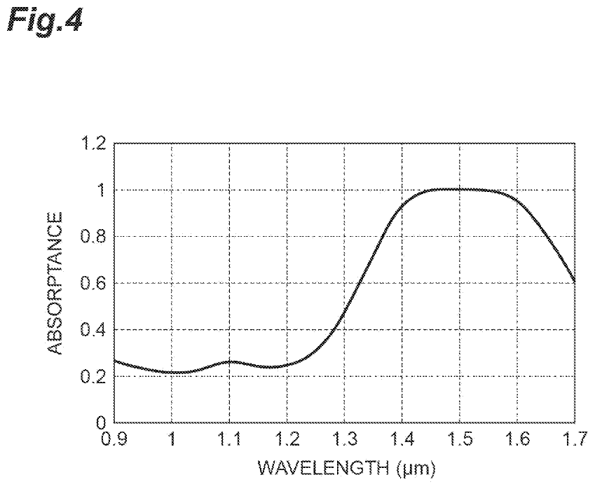

FIG. 4 is a view illustrating a simulation result of an absorption wavelength region by an optical detection element of an example. The absorption wavelength region by the optical detection element 1 is determined mainly by the width of each of the second metal layers 5 in the X-direction and the thickness of the photoelectric conversion layer 4. Here, simulation was carried out in a state in which the width of each of the second metal layers 5 in the X-direction was set to 320 nm, and the thickness of the photoelectric conversion layer 4 composed of Ge is set to 60 nm. As a result, as illustrated in FIG. 4, an absorptance of approximately 100% was obtained with respect to light (polarized light whose electric field direction is the X-direction) in a wavelength region of 1.45 to 1.55 μm.

### Modification Example

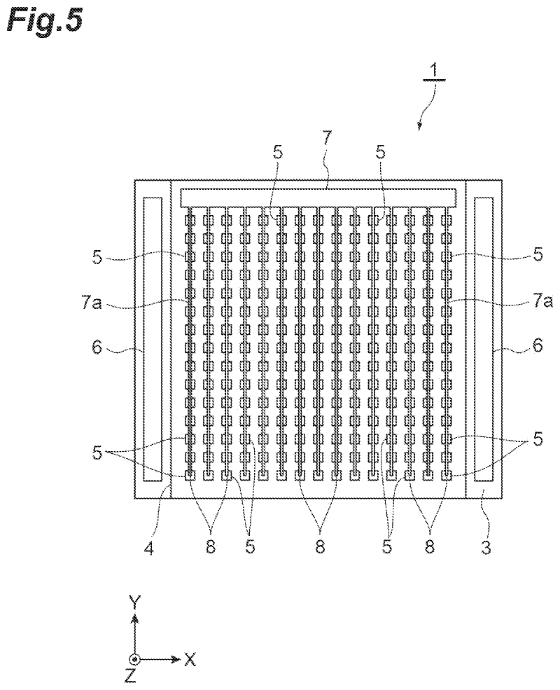

The present disclosure is not limited to the above-described embodiment. For example, as illustrated in FIG. 5, each of the second metal layers 5 may be formed in a square shape when viewed in the Z-direction. In an optical detection element 1 illustrated in FIG. 5, the width of each of the second metal layers 5 in the X-direction and the width of each of the second metal layers 5 in the Y-direction are set to widths with which surface plasmon resonance occurs due to incidence of light hv in a short-wave infrared region. In the optical detection element 1 illustrated in FIG. 5, a plurality of the second metal layers 5 are arranged in a matrix shape in which the X-direction is set as a row direction and the Y-direction is set as a column direction. In the optical detection element 1 illustrated in FIG. 5, a plurality of wirings 7a are formed on the photoelectric conversion layer 4, and each of the wirings 7a is stretched over the plurality of second metal layers 5 arranged in the Y-direction. Accordingly, the plurality of second metal layers 5 are electrically connected to the second electrode 7.

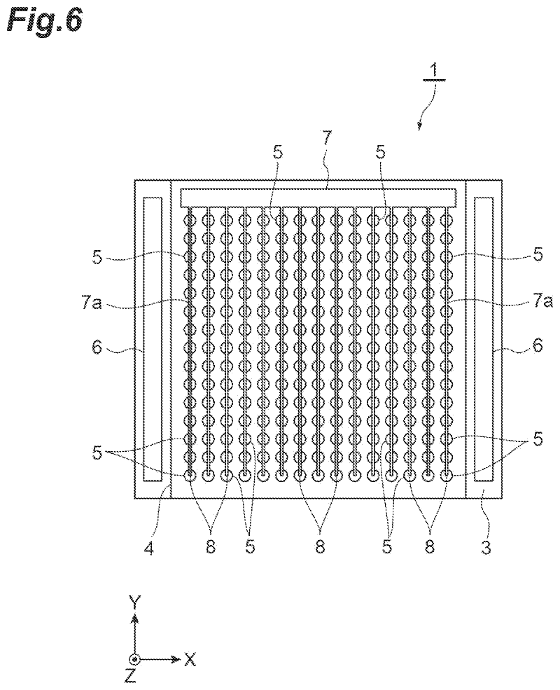

As illustrated in FIG. 6, the second metal layers 5 may be formed in a circular shape when viewed in the Z-direction. In the optical detection element 1 illustrated in FIG. 6, a width in all directions orthogonal to the Z-direction is set to a width with which surface plasmon resonance occurs due to incidence of the light hv in a short-wave infrared region. In the optical detection element 1 illustrated in FIG. 6, the plurality of second metal layers 5 are arranged in a matrix shape in which the X-direction is set as a row direction and the Y-direction is set as a column direction. In the optical detection element 1 illustrated in FIG. 6, a plurality of wirings 7a are formed on the photoelectric conversion layer 4 and each of the wirings 7a is stretched over the plurality of second metal layers 5 arranged in the Y-direction. Accordingly, the plurality of second metal layers 5 are electrically connected to the second electrode 7.

In the method of manufacturing the optical detection elements 1 illustrated in FIG. 5 and FIG. 6, in the fourth process, the plurality of second metal layers 5 are formed so that the width of each of the second metal layers 5 in the Y-direction becomes equal to the width of each of the second metal layers 5 in the X-direction. According to this, it is possible to obtain the optical detection element 1 that can detect polarized light whose electric field direction is the X-direction and polarized light whose electric field direction is the Y-direction in the light hv in a short-wave infrared region.

In the method of manufacturing the optical detection elements 1 illustrated in FIG. 5 and FIG. 6, in the fourth process, the plurality of second metal layers 5 are formed to be arranged in a two-dimensional shape. According to this, it is possible to obtain the optical detection element 1 that can detect polarized light whose electric field direction is the X-direction and polarized light whose electric field direction is the Y-direction in the light hv in a short-wave infrared region in a wide region parallel to both the X-direction and the Y-direction. Particularly, according to the optical detection element 1 illustrated in FIG. 6, it is possible to detect the light hv in a short-wave infrared region in a wide region in a state without polarization dependency (that is, in a state having sensitivity with respect to polarized light whose electric field directions are all directions orthogonal to the Z-direction).

In the support 2, the silicon oxide film 22 may not be formed on the silicon substrate 21. The support 2 may be a substrate or the like other than the semiconductor substrate. The number, the shape, the position, and the like of the first electrode 6 and the second electrode 7 are not limited to the above-described configuration.

The photoelectric conversion layer 4 may be a polycrystalline layer formed by a material other than the material containing any one among Ge, Si, Si—Ge, and Ge—Sn. In this case, in the method of manufacturing the optical detection element 1, the semiconductor layer 40 is formed by a material other than the material containing any one among Ge, Si, Si—Ge, and Ge—Sn. The material of the semiconductor layer 40 and the photoelectric conversion layer 4 is determined in accordance with a wavelength region of detection target light. That is, the optical detection element 1 may be an element configured to detect light in a wavelength region other than the short-wave infrared region.

In a case where the optical detection element 1 is an element configured to detect light in a wavelength region other than the short-wave infrared region, the width of each of the second metal layers 5 in the X-direction may be set to a width with which surface plasmon resonance occurs due to incidence of light in the wavelength region. In this case, in the method of manufacturing the optical detection element 1, the plurality of second metal layers 5 are formed so that the width of each of the second metal layers 5 in the X-direction becomes a width with which surface plasmon resonance occurs due to incidence of light in the wavelength region.

In the method of manufacturing the optical detection element 1, when the heat treatment is carried out so that the semiconductor layer 40 is polycrystallized and the semiconductor layer 40 and the first metal layer 3 are interchanged with each other, the temperature in the heat treatment may be a temperature other than the temperature of 250° C. to 500° C. When the heat treatment is carried out so that the semiconductor layer 40 is polycrystallized and the semiconductor layer 40 and the first metal layer 3 are interchanged with each other, polycrystallization of the semiconductor layer 40 and interchanging of the semiconductor layer 40 and the first metal layer 3 may progress simultaneously or may progress with temporal deviation.

In the above-described embodiment, the first metal layer 3 forms the ohmic junction with the P-type photoelectric conversion layer 4, and each of the second metal layers 5 forms the Schottky junction with the P-type photoelectric conversion layer 4 to constitute the Schottky diode. However, the first metal layer 3 and each of the second metal layers 5 may form the ohmic junction with the P-type photoelectric conversion layer 4 to constitute a photoconductor. In this case, as the material of the first metal layer 3, for example, Au or Al is suitable, and as the material of the second metal layers 5, for example, Au, Pt, Pt/Au, or Al is suitable. Alternatively, a PN junction diode may be constituted by forming an N-type region in a region opposite to the first metal layer 3 in the P-type photoelectric conversion layer 4 by doping with impurities. In this case, as the material of the first metal layer 3, for example, Au or Al is suitable, and as the material of the second metal layers 5, for example, Ti, Ti/Au, or Ti/Al is suitable.

The photoelectric conversion layer 4 may be an N-type polycrystalline layer. In a case where the photoelectric conversion layer 4 is the N-type layer, the first metal layer 3 may form the ohmic junction with the N-type photoelectric conversion layer 4, and each of the second metal layers 5 may form the Schottky junction with the N-type photoelectric conversion layer 4 to constitute the Schottky diode. In this case, as the material of the first metal layer 3, for example, Ti is suitable, and as the material of the second metal layers 5, for example, Au, Pt, Pt/Au, or Al is suitable. Alternatively, the first metal layer 3 and each of the second metal layers 5 may form the ohmic junction with the N-type photoelectric conversion layer 4 to constitute the photoconductor. In this case, as the material of the first metal layer 3, for example, Ti is suitable, and as the material of the second metal layers 5, for example, Ti, Ti/Au, or Ti/Al is suitable. Alternatively, a PN junction diode may be constituted by forming a P-type region in the region opposite to the first metal layer 3 in the N-type photoelectric conversion layer 4 by doping with impurities. In this case, as the material of the first metal layer 3, for example, Ti is suitable, and as a material of the second metal layers 5, for example, Au, Pt, Pt/Au, or Al is suitable.

Even in any of the optical detection elements 1, at least one second metal layer 5 may be formed on the photoelectric conversion layer 4. In addition, even in the method of manufacturing any of the optical detection elements 1, at least one second metal layer 5 may be formed so that the width of the second metal layer 5 in at least one direction (first direction orthogonal to the thickness direction of the second metal layer 5) becomes a width with which surface plasmon resonance occurs due to incidence of light in a predetermined wavelength region.

A method of manufacturing an optical detection element according to an aspect of the present disclosure is [1] “a method of manufacturing an optical detection element, including: a first process of forming an amorphous semiconductor layer on a support; a second process of forming a first metal layer on the semiconductor layer; a third process of carrying out a heat treatment so that the semiconductor layer is polycrystallized and the semiconductor layer and the first metal layer are interchanged with each other, thereby forming the first metal layer on the support and forming a polycrystalline photoelectric conversion layer on the first metal layer; and a fourth process of forming a second metal layer on the photoelectric conversion layer, wherein in the fourth process, the second metal layer is formed so that a width of the second metal layer in a first direction orthogonal to a thickness direction of the second metal layer becomes a width with which surface plasmon resonance occurs due to incidence of light in a predetermined wavelength region”.

In the method of manufacturing an optical detection element described in [1], after the amorphous semiconductor layer is formed on the support, and the first metal layer is formed on the semiconductor layer, the heat treatment is carried out so that the semiconductor layer is polycrystallized and the semiconductor layer and the first metal layer are interchanged with each other. According to this, it is possible to easily obtain a configuration in which the first metal layer and the polycrystalline photoelectric conversion layer are formed on the support in this order. Furthermore, the second metal layer is formed on the photoelectric conversion layer so that the width of the second metal layer at least in the first direction becomes a width with which surface plasmon resonance occurs due to incidence of light in a predetermined wavelength region. According to this, in the optical detection element, when light in a predetermined wavelength region is incident, surface plasmon resonance occurs between the first metal layer and the second metal layer, and light condensing efficiency at the photoelectric conversion layer is raised due to an optical antenna effect, and as a result, sensitivity to light in a predetermined wavelength region is raised. Accordingly, according to the method of manufacturing an optical detection element described in [1], it is possible to easily manufacture an optical detection element having high sensitivity to light in a predetermined wavelength region.

The method of manufacturing an optical detection element according to the aspect of the present disclosure may be [2] “the method of manufacturing an optical detection element according to [1], wherein in the first process, the semiconductor layer is formed by a material containing any one among Ge, Si, Si—Ge, and Ge—Sn”. According to the method of manufacturing an optical detection element described in [2], in the polycrystalline photoelectric conversion layer formed by a material containing any one among Ge, Si, Si—Ge, and Ge—Sn, photoelectric conversion efficiency can be raised with respect to light in a short-wave infrared region.

The method of manufacturing an optical detection element according to the aspect of the present disclosure may be [3] “the method of manufacturing an optical detection element according to [1] or [2], wherein in the fourth process, the second metal layer is formed so that the width of the second metal layer in the first direction becomes a width with which surface plasmon resonance occurs due to incidence of light with a wavelength of 0.9 μm to 1.8 μm”. According to the method of manufacturing the optical detection element described in [3], light condensing efficiency at the photoelectric conversion layer can be raised with respect to light in a short-wave infrared region.

The method of manufacturing an optical detection element according to the aspect of the present disclosure may be [4] “the method of manufacturing an optical detection element according to any one of [1] to [3], wherein in the fourth process, the second metal layer is formed to extend in a long shape with a second direction orthogonal to both the thickness direction and the first direction set as a longitudinal direction”. According to the method of manufacturing an optical detection element described in [4], it is possible to obtain an optical detection element that can detect polarized light whose electric field direction is the first direction in the light in a predetermined wavelength region in the entirety of the second metal layers extending in the second direction.

The method of manufacturing an optical detection element according to the aspect of the present disclosure may be [5] “the method of manufacturing an optical detection element according to [4], wherein in the fourth process, as the second metal layer, a plurality of second metal layers arranged in the first direction are formed”. According to the method of manufacturing an optical detection element described in [5], it is possible to obtain an optical detection element that can detect polarized light whose electric field direction is the first direction in the light in a predetermined wavelength region in a wide region parallel to both the first direction and the second direction.

The method of manufacturing an optical detection element according to the aspect of the present disclosure may be [6] “the method of manufacturing an optical detection element according to any one of [1] to [3], wherein in the fourth process, the second metal layer is formed so that a width of the second metal layer in a second direction orthogonal to both the thickness direction and the first direction becomes equal to a width of the second metal layer in the first direction”. According to the method of manufacturing an optical detection element described in [6], it is possible to obtain an optical detection element that can detect polarized light whose electric field direction is the first direction and polarized light whose electric field direction is the second direction in the light in a predetermined wavelength region.

The method of manufacturing an optical detection element according to the aspect of the present disclosure may be [7] “the method of manufacturing an optical detection element according to [6], wherein in the fourth process, a plurality of the second metal layers which are two-dimensionally arranged are formed as the second metal layer”. According to the method of manufacturing an optical detection element described in [7], it is possible to obtain an optical detection element that can detect polarized light whose electric field direction is the first direction and polarized light whose electric field direction is the second direction in the light in a predetermined wavelength region in a wide region parallel to both the first direction and the second direction.

The method of manufacturing an optical detection element according to the aspect of the present disclosure may be [8] “the method of manufacturing an optical detection element according to any one of [1] to [7], wherein in the third process, the heat treatment is carried out at a temperature of 250° C. to 500° C.”. According to the method of manufacturing an optical detection element described in [8], since polycrystallization of the semiconductor layer and interchanging of the semiconductor layer and the first metal layer are appropriately realized, it is possible to reliably obtain a configuration in which the first metal layer and the polycrystalline photoelectric conversion layer are formed on the support in this order.

An optical detection element according to another aspect of the present disclosure is [9] “an optical detection element including: a support; a first metal layer formed on the support; a polycrystalline photoelectric conversion layer formed on the first metal layer; and a second metal layer formed on the photoelectric conversion layer, wherein a width of the second metal layer in a first direction orthogonal to a thickness direction of the second metal layer is a width with which surface plasmon resonance occurs due to incidence of light in a predetermined wavelength region”.

In the optical detection element described in [9], when light in a predetermined wavelength region is incident, surface plasmon resonance occurs between the first metal layer and the second metal layer, and light condensing efficiency at the photoelectric conversion layer is raised due to an optical antenna effect, and as a result, sensitivity to light in a predetermined wavelength region is raised. Accordingly, according to the optical detection element described in [9], light in a predetermined wavelength region can be detected with high sensitivity.

According to the present disclosure, it is possible to provide a method of manufacturing an optical detection element which is capable of easily manufacturing an optical detection element having high sensitivity to light in a predetermined wavelength region, and an optical detection element.

What is claimed is:

1. A method of manufacturing an optical detection element, comprising:
a first process of forming an amorphous semiconductor layer on a support;
a second process of forming a first metal layer on the semiconductor layer;
a third process of carrying out a heat treatment so that the semiconductor layer is polycrystallized and the semiconductor layer and the first metal layer are interchanged with each other, thereby forming the first metal layer on the support and forming a polycrystalline photoelectric conversion layer on the first metal layer; and
a fourth process of forming a second metal layer on the photoelectric conversion layer,
wherein in the fourth process, the second metal layer is formed so that a width of the second metal layer in a first direction orthogonal to a thickness direction of the second metal layer becomes a width with which surface plasmon resonance occurs due to incidence of light in a predetermined wavelength region.

2. The method of manufacturing an optical detection element according to claim 1,
wherein in the first process, the semiconductor layer is formed by a material containing any one among Ge, Si, Si—Ge, and Ge—Sn.

3. The method of manufacturing an optical detection element according to claim 1,
wherein in the fourth process, the second metal layer is formed so that the width of the second metal layer in the first direction becomes a width with which surface plasmon resonance occurs due to incidence of light with a wavelength of 0.9 μm to 1.8 μm.

4. The method of manufacturing an optical detection element according to claim 1,
wherein in the fourth process, the second metal layer is formed to extend in a long shape with a second direction orthogonal to both the thickness direction and the first direction set as a longitudinal direction.

5. The method of manufacturing an optical detection element according to claim 4,
wherein in the fourth process, as the second metal layer, a plurality of second metal layers arranged in the first direction are formed.

6. The method of manufacturing an optical detection element according to claim 1,
wherein in the fourth process, the second metal layer is formed so that a width of the second metal layer in a second direction orthogonal to both the thickness direction and the first direction becomes equal to a width of the second metal layer in the first direction.

7. The method of manufacturing an optical detection element according to claim 6,
wherein in the fourth process, a plurality of the second metal layers which are two-dimensionally arranged are formed as the second metal layer.

8. The method of manufacturing an optical detection element according to claim 1,
wherein in the third process, the heat treatment is carried out at a temperature of 250° C. to 500° C.

9. An optical detection element, comprising:
a support;
a first metal layer formed on the support;
a polycrystalline photoelectric conversion layer formed on the first metal layer; and
a second metal layer formed on the photoelectric conversion layer,
wherein a width of the second metal layer in a first direction orthogonal to a thickness direction of the second metal layer is a width with which surface plasmon resonance occurs due to incidence of light in a predetermined wavelength region.
